(19) United States
(12) Patent Application Publication
(10) Pub. No.: US 2018/0238750 A1
(43) Pub. Date: Aug. 23, 2018

(54) PRESSURE SENSOR AND MANUFACTURING METHOD THEREOF

(71) Applicant: Winbond Electronics Corp., Taichung City (TW)

(72) Inventors: Yu-Hsuan Ho, Taichung City (TW); Ming-Chih Tsai, Taichung City (TW); Ming-Hung Hsieh, Taichung City (TW)

(73) Assignee: Winbond Electronics Corp., Taichung City (TW)

(21) Appl. No.: 15/844,654

(22) Filed: Dec. 18, 2017

(30) Foreign Application Priority Data
Feb. 23, 2017 (CN) 201710099622.8

(51) Int. Cl. G01L 1/14; G01L 1/20; H01L 29/41

(52) U.S. Cl. CPC G01L 1/142; H01L 29/413; G01L 1/20

(57) ABSTRACT

A pressure sensor and a manufacturing method thereof are provided. The pressure sensor includes a first electrode, a pressure-sensitive layer covering the first electrode, and a second electrode covering the pressure-sensitive layer. A support material is contained in the pressure-sensitive layer, and the support material is a nano-sized material with an aspect ratio between 100 and 5000. Mechanical property of the pressure-sensitive layer in the pressure sensor can be improved by the property of the nano-sized material.

### CROSS-REFERENCE TO RELATED APPLICATION

This application claims the priority benefits of China application serial no. 201710099622.8, filed on Feb. 23, 2017. The entirety of the above-mentioned patent application is hereby incorporated by reference herein and made a part of this specification.

### BACKGROUND OF THE INVENTION

### Field of the Invention

The invention relates to a pressure sensing technique, and particularly relates to a pressure sensor and a manufacturing method thereof.

### Description of Related Art

With the advance of science and technology, a wide variety of electronic products all develop toward light, thin, short, and small in size. In touch control devices, the size of pressure sensors is the key of the development thereof toward light, thin, short, and small. However, in the present, when the pressure sensor is reduced to a certain size, a pressure-sensitive deformation layer in the pressure sensor cannot completely return to an original shape after being subject to the pressure to be deformed due to lack of mechanical strength, and the lifetime of the pressure sensor is significantly decreased. Based on the above, it is desired to develop a pressure sensor which can solve the aforementioned problems.

### SUMMARY OF THE INVENTION

The invention provides a pressure sensor having excellent mechanical strength, so as to improve the lifetime of the pressure sensor.

The invention also provides a manufacturing method of a pressure sensor, which can manufacture the pressure sensor having excellent mechanical strength, so as to improve the lifetime of the pressure sensor.

A pressure sensor of the invention includes a first electrode, a pressure-sensitive layer covering the first electrode, and a second electrode located on the pressure-sensitive layer. The pressure-sensitive layer includes a support material. The support material includes a nano-sized material with an aspect ratio between 100 and 5000.

A manufacturing method of the pressure sensor of the invention includes the following steps. A first electrode is formed. A pressure-sensitive layer covering the first electrode is formed using 3D printing. Then, a second electrode is formed on the pressure-sensitive layer. The pressure-sensitive layer includes a support material. The support material includes a nano-sized material with an aspect ratio between 100 and 5000.

Based on the above, the pressure-sensitive layer of the invention includes the nano-sized material having high stiffness, high strength, and high aspect ratio, and thus the mechanical property of the pressure sensor can be significantly improved. Even in the case of small component size, the pressure sensor can still return to an original shape after being subject to the pressure to be deformed, and thus the lifetime of the pressure sensor can be significantly improved. Additionally, since the pressure sensor of the invention is manufactured by 3D printing technique, the material (e.g., nano-cellulose), which is difficult to mix with the pressure-sensitive layer originally, can be perfectly mixed to the pressure-sensitive layer, so as to obtain the pressure sensor having high mechanical strength.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a schematic view of a resistive pressure sensor according to an embodiment of the invention without being subject to pressure.

FIG. 1B is a cross-sectional view of the resistive pressure sensor of FIG. 1A being subject to the pressure.

FIG. 2A is a schematic view of a capacitive pressure sensor according to another embodiment of the invention without being subject to the pressure.

FIG. 2B is a cross-sectional view of the capacitive pressure sensor of FIG. 2A being subject to the pressure.

FIG. 3 to FIG. 5 are schematic cross-sectional views of a process flow of the pressure sensor according to yet another embodiment of the invention.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The pressure sensor of the invention may be a resistive pressure sensor or a capacitive pressure sensor. The different embodiments accompanied with figures will be described in detail below.

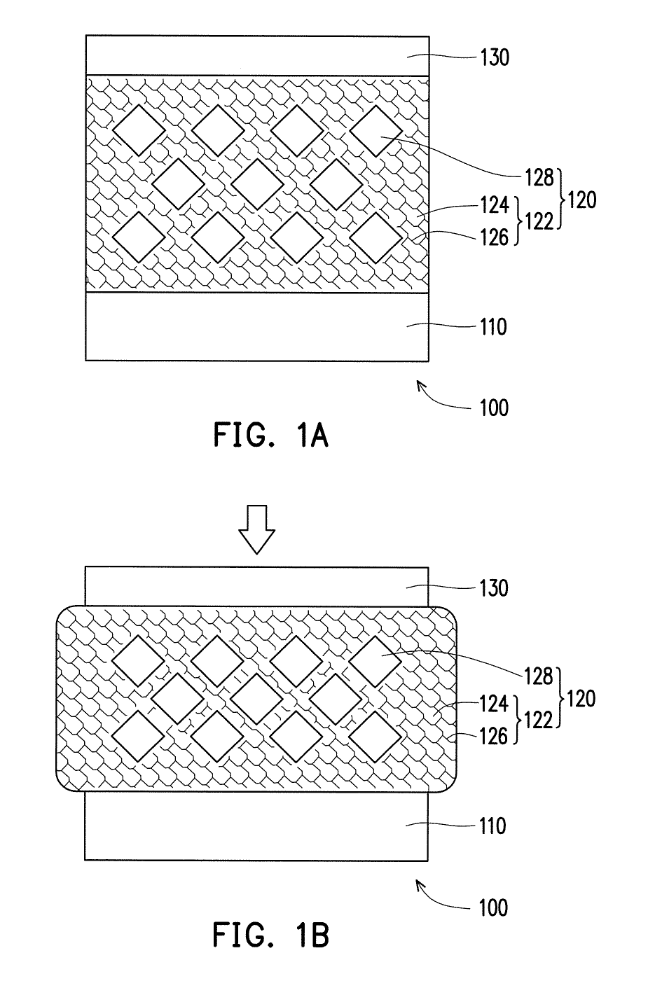

FIG. 1A and FIG. 1B are cross-sectional views of a resistive pressure sensor according to an embodiment of the invention before and after being subject to the pressure respectively. Referring to FIG. 1A to FIG. 1B at the same time, in the embodiment, a resistive pressure sensor 100 includes a first electrode 110, a pressure-sensitive layer 120 covering the first electrode 110, and a second electrode 130 located on the pressure-sensitive layer 120. The pressure-sensitive layer 120 includes conductive particles 128 and a support material 122. The support material 122 includes a nano-sized material 126 with an aspect ratio between 100 and 5000. The so-called “aspect ratio” means that a ratio of length to diameter of the nano-sized material 126. A diameter of the nano-sized material 126 is, for example, between 5 nanometers and 20 nanometers, such as 5 nanometers, 10 nanometers, 15 nanometers, or 20 nanometers. A length of the nano-sized material 126 is, for example, equal to or more than 1 micron, preferably between 1 micron and 10 microns.

In the embodiment, the support material 122 in the pressure-sensitive layer 120 includes a polymer material 124 and the nano-sized material 126, for example. A weight ratio of the nano-sized material 126 to the polymer material 124 is, for example, 0.005 to 0.3, such as 0.005, 0.01, 0.015, 0.02, 0.025, or 0.3. If the total amount of the pressure-sensitive layer 120 is 100 wt %, the content of the support material 122 is, for example, 70 wt % to 90 wt %, such as 70 wt %, 75 wt %, 80 wt %, 85 wt %, or 90 wt %, and the rest is conductive particles 128. For example, the content of the conductive particles 128 in the pressure-sensitive layer 120 is 10 wt % to 30 wt %. The polymer material 124 is polystyrene, epoxy resins, polylactic acid, polyethylene, low-density polyethylene, polymethylmethacrylate, polycarbonate, polyacrylonitrile, polydimethylsiloxane, or a combination thereof, for example.

In the embodiment, the nano-sized material 126 is a nonconductor or a conductor, such as nano-cellulose, Kevlar fibers, steel wires, nano-clay sheets, carbon fibers, carbon nanotubes, amide fibers, boron fibers, polyamide thixotropes, or other organic materials or inorganic materials. In the case of the nano-sized material 126, the nano-cellulose is preferred. Since the pressure-sensitive layer 120 of the resistive pressure sensor 100 in the embodiment is formed by the nano-sized material 126 having high stiffness, high strength, and high aspect ratio wound around each other, the mechanical property of the resistive pressure sensor 100 is significantly improved. Accordingly, even in the case of small component size, the resistive pressure sensor 100 can return to the original shape after being subject to the pressure to be deformed, and the lifetime of the resistive pressure sensor 100 is significantly improved.

As for the operation of the embodiment of the invention, referring to FIG. 1A, when the pressure is not applied, the distance between the conductive particles 128 in the pressure-sensitive layer 120 is longer. At this time, the current is difficult to transfer between the conductive particles 128, and the resistive pressure sensor 100 is in a high resistance state. When the pressure is applied to the resistive pressure sensor 100 in the direction of the arrow in FIG. 1B, the distance between the conductive particles 128 in the pressure-sensitive layer 120 is shortened. At this time, the current is easy to transfer between the conductive particles 128, and the resistive pressure sensor 100 is in a low resistance state. Thus, the change in pressure can be measured by the change in resistance. After stopping applying the pressure to the resistive pressure sensor 100, the resistive pressure sensor 100 can return to the state of FIG. 1A with the help of the nano-sized material 126.

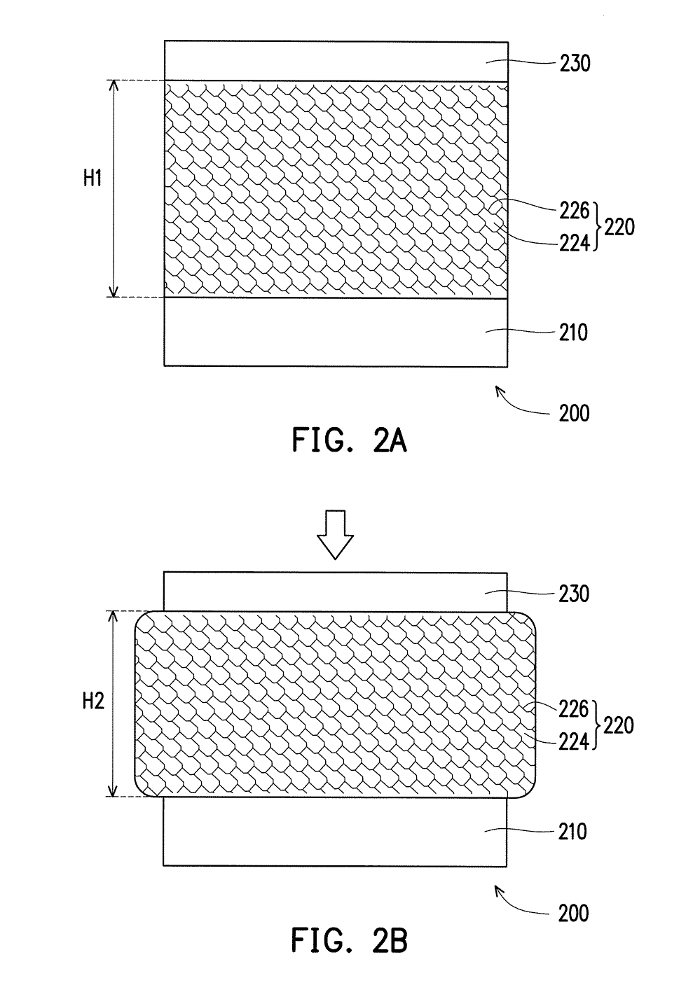

FIG. 2A and FIG. 2B are cross-sectional views of a capacitive pressure sensor according to another embodiment of the invention before and after being subject to the pressure respectively. Referring to FIG. 2A to FIG. 2B at the same time, in the embodiment, a capacitive pressure sensor 200 includes a first electrode 210, a pressure-sensitive layer 220 covering the first electrode 210, and a second electrode 230 located on the pressure-sensitive layer 220. The pressure-sensitive layer 220 includes a support material. The support material includes a nano-sized material 226 with an aspect ratio between 100 and 5000. The so-called “aspect ratio” means that a ratio of length to diameter of the nano-sized material 226. A diameter of the nano-sized material 226 is, for example, between 5 nanometers and 20 nanometers, such as 5 nanometers, 10 nanometers, 15 nanometers, or 20 nanometers. A length of the nano-sized material 226 is, for example, equal to or more than 1 micron, preferably between 1 micron and 10 microns.

In the embodiment, the support material in the pressure-sensitive layer 220 may further include a polymer material 224. The polymer material 224 is polystyrene, epoxy resins, polylactic acid, polyethylene, low-density polyethylene, polymethylmethacrylate, polycarbonate, polyacrylonitrile, polydimethylsiloxane, or a combination thereof, for example. In the embodiment, the support material in the pressure-sensitive layer 220 includes the polymer material 224 and the nano-sized material 226 simultaneously, for example. A weight ratio of the nano-sized material 226 to the polymer material 224 is, for example, 0.001 to 0.3, such as 0.001, 0.005, 0.01, 0.015, 0.02, 0.025, or 0.3.

In the embodiment, the nano-sized material 226 is a nonconductor or a conductor, such as nano-cellulose, Kevlar fibers, steel wires, nano-clay sheets, carbon fibers, carbon nanotubes, amide fibers, boron fibers, polyamide thixotropes, or other organic materials or inorganic materials. In the case of the nano-sized material 226, the nano-cellulose is preferred. Since the pressure-sensitive layer 220 of the capacitive pressure sensor 200 of the embodiment is formed by the nano-sized material 226 having high stiffness, high strength, and high aspect ratio wound around each other, the mechanical property of the capacitive pressure sensor 200 is significantly improved. Thus, even in the case of small component size, the capacitive pressure sensor 200 can return to the original shape after being subject to the pressure to be deformed, and the lifetime of the capacitive pressure sensor 200 is significantly improved.

As for the operation of the embodiment of the invention, referring to FIG. 2A, when the pressure is not applied, the distance between the first electrode 210 and the second electrode 230 in the pressure-sensitive layer 220 is longer, for example, a distance H1 between the first electrode 210 and the second electrode 230. At this time, a capacitance between the first electrode 210 and the second electrode 230 is lower, and the capacitive pressure sensor 200 is in a low capacitance state. When the pressure is applied to the capacitive pressure sensor 200 in the direction of the arrow in FIG. 2B, the distance between the first electrode 210 and the second electrode 230 is shortened, for example, a distance H2 between the first electrode 210 and the second electrode 230. At this time, the capacitance between the first electrode 210 and the second electrode 230 is higher, and the capacitive pressure sensor 200 is in a high capacitance state. Thus, the change in pressure can be measured by the change in capacitance. After stopping applying the pressure to the capacitive pressure sensor 200, the resistive pressure sensor 200 can return to the state of FIG. 2A with the help of the nano-sized material 226.

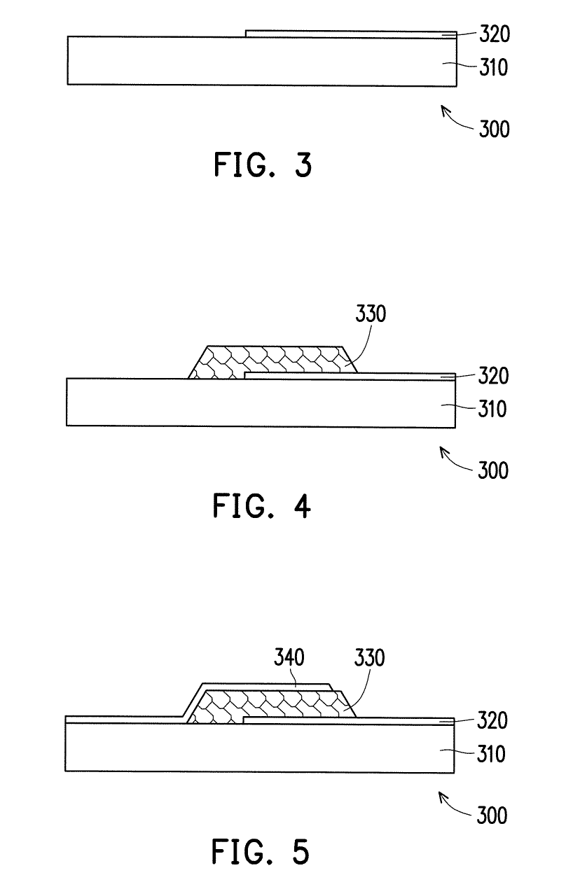

As for the process flow of the pressure sensor of the embodiment of the invention, referring to FIG. 3, a first electrode 320 is formed. A method of forming the first electrode 320 is 3D printing, for example. The first electrode 320 is usually electrically connected to a source in a thin film transistor (not shown) on a substrate 310, for example, but the invention is not limited thereto.

Then, referring to FIG. 4, a pressure-sensitive layer 330 covering the first electrode 320 is formed by the 3D printing. The pressure-sensitive layer 330 is the same as the pressure-sensitive layer in the aforementioned embodiments, which includes the nano-sized material, and will not be repeated. Additionally, for different needs, the conductive particles or the polymer material can be added into the ink of the 3D printing before forming the pressure-sensitive layer 330. Both the additive amount of the conductive particles and the type and content of the polymer material can be referred to the aforementioned embodiments, and will not be repeated.

In FIG. 4, the pressure-sensitive layer 330 only covers a portion of the first electrode 320, and the first electrode 320 exposes a portion of the pressure-sensitive layer 330, but the invention is not limited thereto. The pressure-sensitive layer 330 may also completely cover the first electrode 320.

Then, referring to FIG. 5, a second electrode 340 is formed on the pressure-sensitive layer 330. A method of forming the second electrode 340 is 3D printing, for example. In FIG. 5, the second electrode 340 covers a portion of the pressure-sensitive layer 330, and the second electrode 340 extends onto the substrate 310 which is not covered by the pressure-sensitive layer 330, but the invention is not limited thereto. The second electrode 340 may be only located on the pressure-sensitive layer 330 and without extending to the substrate 310. Alternatively, the second electrode 340 may completely cover the pressure-sensitive layer 330.

In FIG. 3 to FIG. 5, only one pressure sensor 300 is illustrated, but the invention is not limited thereto. An array composed of a plurality of pressure sensors can be formed by the 3D printing technique simultaneously in the invention.

In summary, the pressure-sensitive layer includes the nano-sized material having high stiffness, high strength, and high aspect ratio in the invention, and the mechanical property of the pressure sensor can be significantly improved. Thus, even in the case of small component size, the pressure sensor can return to the original shape after being subject to the pressure to be deformed, and the lifetime of the pressure sensor is significantly improved. Additionally, since the pressure sensor of the invention is manufactured using the 3D printing technique, the material (e.g., nano-cellulose), which is difficult to mix with the pressure-sensitive layer originally, can be perfectly mixed to the pressure-sensitive layer, so as to obtain the pressure sensor having high mechanical strength.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A pressure sensor, comprising:
a first electrode;
a pressure-sensitive layer, covering the first electrode, wherein the pressure-sensitive layer comprises a support material, and the support material comprises a nano-sized material with an aspect ratio between 100 and 5000; and
a second electrode, located on the pressure-sensitive layer.

2. The pressure sensor according to claim 1, wherein a diameter of the nano-sized material is 5 nanometers to 20 nanometers, and a length of the nano-sized material is 1 micron to 10 microns.

3. The pressure sensor according to claim 1, wherein the nano-sized material comprises nano-cellulose, Kevlar fibers, steel wires, nano-clay sheets, carbon fibers, carbon nanotubes, amide fibers, boron fibers, or polyamide thixotropes.

4. The pressure sensor according to claim 1, wherein the support material further comprises a polymer material.

5. The pressure sensor according to claim 4, wherein the polymer material comprises polystyrene, epoxy resins, polylactic acid, polyethylene, low-density polyethylene, polymethylmethacrylate, polycarbonate, polyacrylonitrile, polydimethylsiloxane, or a combination thereof.

6. The pressure sensor according to claim 4, wherein a weight ratio of the nano-sized material to the polymer material in the support material is 0.001 to 0.3.

7. The pressure sensor according to claim 1, wherein the pressure-sensitive layer further comprises a plurality of conductive particles.

8. The pressure sensor according to claim 7, wherein the content of the conductive particles in the pressure-sensitive layer is 10 wt % to 30 wt %.

9. The pressure sensor according to claim 7, wherein the content of the support material in the pressure-sensitive layer is 70 wt % to 90 wt %.

10. The pressure sensor according to claim 7, wherein the support material further comprises a polymer material.

11. The pressure sensor according to claim 10, wherein a weight ratio of the nano-sized material to the polymer material in the support material is 0.005 to 0.3.

12. A manufacturing method of a pressure sensor, comprising:
forming a first electrode;
forming a pressure-sensitive layer covering the first electrode by a first 3D printing, wherein the pressure-sensitive layer comprises a support material, and the support material comprises a nano-sized material with an aspect ratio between 100 and 5000; and
forming a second electrode on the pressure-sensitive layer.

13. The manufacturing method of the pressure sensor according to claim 12, wherein a method of forming the first electrode and forming the second electrode comprises a second 3D printing.

14. The manufacturing method of the pressure sensor according to claim 12, wherein before forming the pressure-sensitive layer further comprises: adding a plurality of conductive particles in an ink of the first 3D printing.

15. The manufacturing method of the pressure sensor according to claim 12, wherein before forming the pressure-sensitive layer further comprises: adding a polymer material in an ink of the first 3D printing.

16. The manufacturing method of the pressure sensor according to claim 12, wherein the nano-sized material comprises nano-cellulose, Kevlar fibers, steel wires, nano-clay sheets, carbon fibers, carbon nanotubes, amide fibers, boron fibers, or polyamide thixotropes.
